(19) United States
(12) Patent Application Publication
(10) Pub. No.: US 2025/0330003 A1
(43) Pub. Date: Oct. 23, 2025

(54) ELECTRICAL JUNCTION BOX

(71) Applicant: Sumitomo Wiring Systems, Ltd., Yokkaichi-Shi, Mie (JP)

(72) Inventors: Kiyofumi KAWAGUCHI, Yokkaichi-Shi, Mie (JP); Tatsuya FUJISAKA, Yokkaichi-Shi, Mie (JP)

(73) Assignee: Sumitomo Wiring Systems, Ltd., Yokkaichi-Shi, Mie (JP)

(21) Appl. No.: 18/870,168

(22) PCT Filed: May 17, 2023
(86) PCT No.: PCT/JP2023/018478

§ 371 Date: Nov. 27, 2024

(30) Foreign Application Priority Data
Jun. 1, 2022 (JP) 2022-089776

(51) Int. Cl. H02G 3/08; B60R 16/02

(52) U.S. Cl. CPC H02G 3/081; B60R 16/02

(57) ABSTRACT

An electrical junction box including: a housing; and a relay disposed on one wall that is adjacent to a side wall of the housing so as to be separated from the side wall, wherein a strength-reinforcing portion is provided so as to extend from a central portion of the side wall to a vicinity of the relay.

### CROSS-REFERENCE TO RELATED APPLICATIONS

This application is the U.S. national stage of PCT/JP2023/018478 filed on May 17, 2023, which claims priority of Japanese Patent Application No. JP 2022-089776 filed on Jun. 1, 2022, the contents of which are incorporated herein.

### TECHNICAL FIELD

The present disclosure relates to an electrical junction box.

### BACKGROUND

Conventionally, electrical junction boxes equipped with electronic components such as fuses and relays are installed in a vehicle.

Such an electrical junction box includes a housing, and for example, the housing includes a first case that has one open side and in which the electronic components are provided, and a second case covering the one open side of the first case (see JP 2016-208561A).

The electrical junction box described above is attached to an object such as a vehicle. More specifically, the electrical junction box is fixed to the object with screws or the like.

However, a vehicle vibrates while traveling, and the electrical junction box attached to the vehicle also vibrates in accordance with the vibration of the vehicle. In this regard, such vibration of the electrical junction box may cause loosening of the screws that connect the electrical junction box to the vehicle.

Furthermore, heavy electronic components such as relays provided in the electrical junction box vibrate in conjunction with the vibration of the electrical junction box, thereby affecting the vibration of the electrical junction box. That is to say, the vibration of heavy electronic components such as relays increases the vibration of the electrical junction box, which further loosens the screws that fix the electrical junction box to the vehicle.

However, the electrical junction box according to JP 2016-208561A does not take such problems into consideration and cannot solve the above-mentioned problems.

Therefore, the present disclosure aims to provide an electrical junction box that can suppress vibration of electronic components and prevent loosening of the attachment of the electrical junction box to an object.

### SUMMARY

An electrical junction box according to an embodiment of the present disclosure is an electrical junction box including: a housing; and an electronic component disposed on one wall that is adjacent to a side wall of the housing so as to be separated from the side wall, wherein a strength-reinforcing portion is provided so as to extend from a central portion of the side wall to a vicinity of the electronic component.

### Advantageous Effects

The present disclosure can provide an electrical junction box that can suppress vibration of electronic components and prevent loosening of the attachment of the electrical junction box to an object.

### BRIEF DESCRIPTION OF DRAWINGS

FIG. 1 is a perspective view of an electrical junction box according to an embodiment.

FIG. 2A is a plan view of the electrical junction box according to the embodiment.

FIG. 2B is a side view of the electrical junction box according to the embodiment. FIG. 3 is an exploded view of the electrical junction box according to the embodiment.

FIG. 4 is a bottom perspective view of the electrical junction box according to the embodiment.

FIG. 5 is an exploded view of the electrical junction box according to the embodiment in an upside-down state.

FIG. 6 is a vertical cross-sectional view taken along a VI-VI line in FIG. 4.

### DETAILED DESCRIPTION OF PREFERRED EMBODIMENTS

First, aspects of the present disclosure will be listed and described. At least some of the embodiments described below may be combined in any manner.

An electrical junction box according to an embodiment of the present disclosure is an electrical junction box including: a housing; and an electronic component disposed on one wall that is adjacent to a side wall of the housing so as to be separated from the side wall, wherein a strength-reinforcing portion is provided so as to extend from a central portion of the side wall to a vicinity of the electronic component.

According to such an embodiment, a strength-reinforcing portion is provided so as to extend from a central portion of the side wall to a vicinity of the electronic component. Therefore, the strength-reinforcing portion reinforces the portion between the side wall and the electronic component, thereby suppressing vibration of the electronic component and preventing loosening of the attachment of the electrical junction box to an object.

In the electrical junction box according to the embodiment of the present disclosure, the housing includes a first case that includes the side wall and the one wall, and the strength-reinforcing portion is provided in the first case, and includes an inner wall provided on an inner side with respect to the side wall and curved so as to protrude toward the electronic component, and a rib provided between the inner wall and the side wall.

In such an embodiment, the strength-reinforcing portion includes an inner wall curved so as to protrude from the inner side with respect to the side wall toward the electronic component, and a rib provided between the inner wall and the side wall. Therefore, the portion between the side wall and the electronic component is reinforced, thereby suppressing vibration of the electronic component, and preventing loosening of the attachment of the electrical junction box to an object.

In the electrical junction box according to the embodiment of the present disclosure, the housing includes a second case that closes an opening of the first case formed so as to face the one wall, and a side wall of the second case includes a curved portion corresponding to the inner wall.

In such an embodiment, the side wall of the second case includes a curved portion corresponding to the inner wall, and the curved portion is in contact with and reinforces the inner wall. Therefore, the portion between the side wall and the electronic component is further reinforced, thereby suppressing vibration of the electronic component, and preventing loosening of the attachment of the electrical junction box to an object.

In the electrical junction box according to the embodiment of the present disclosure, the strength-reinforcing portion includes an attachment portion that is used to attach the electrical junction box to an object.

In such an embodiment, the strength-reinforcing portion includes an attachment portion, and when the electrical junction box is to be attached to an object, the attachment portion is fixed to the object. As a result, the strength-reinforcing portion is fixed to the object, thereby suppressing vibration of the electronic component, and preventing loosening of the attachment of the electrical junction box to the object.

Hereinafter, an electrical junction box according to an embodiment of the present disclosure will be described with reference to the drawings. Note that the present disclosure is not limited to these examples, but is defined by the scope of the claims, and is intended to include all modifications within the meaning and scope of the claims.

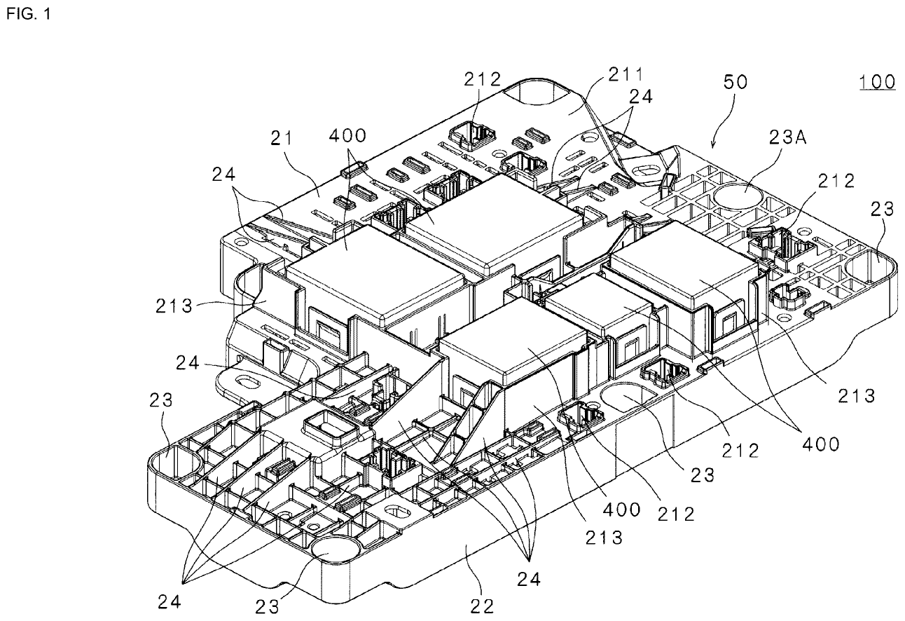

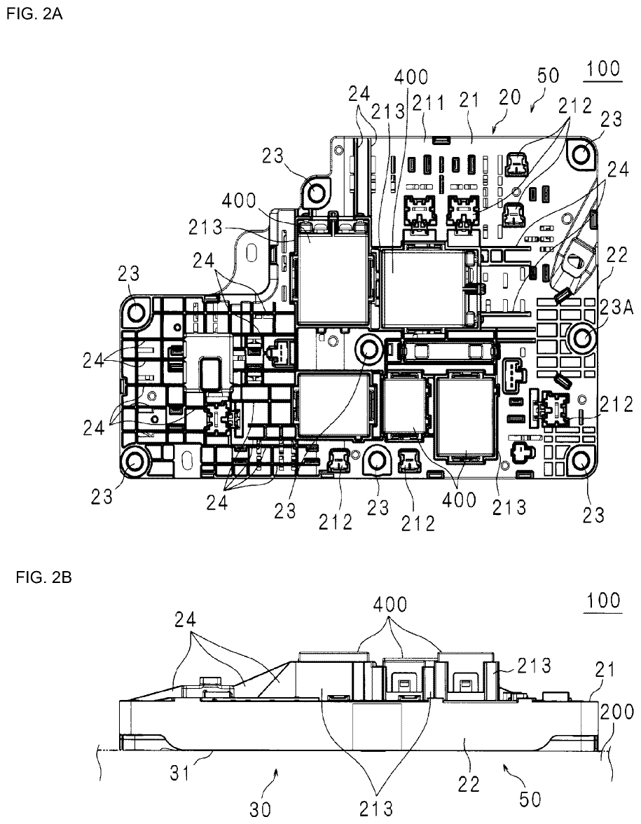

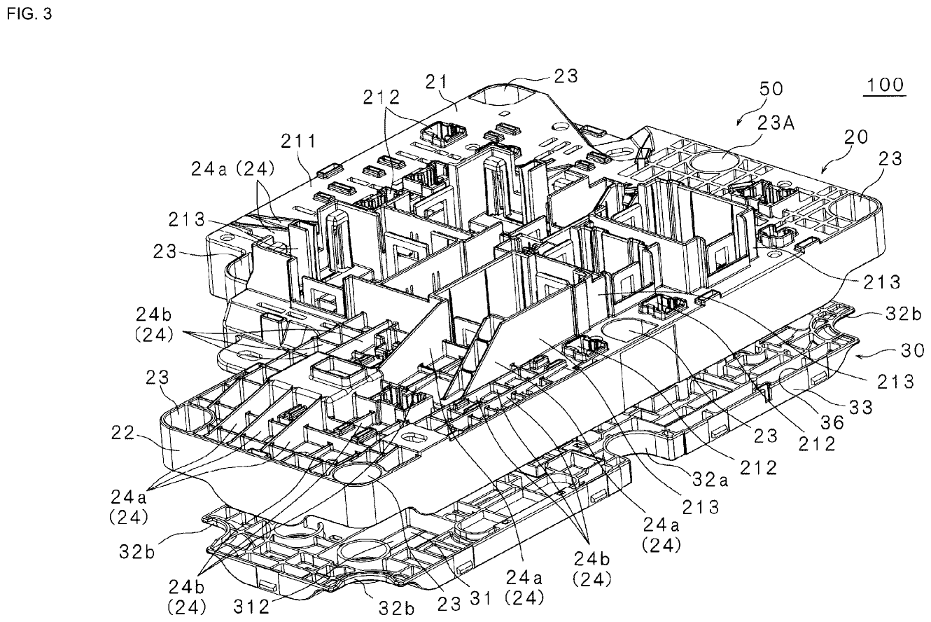

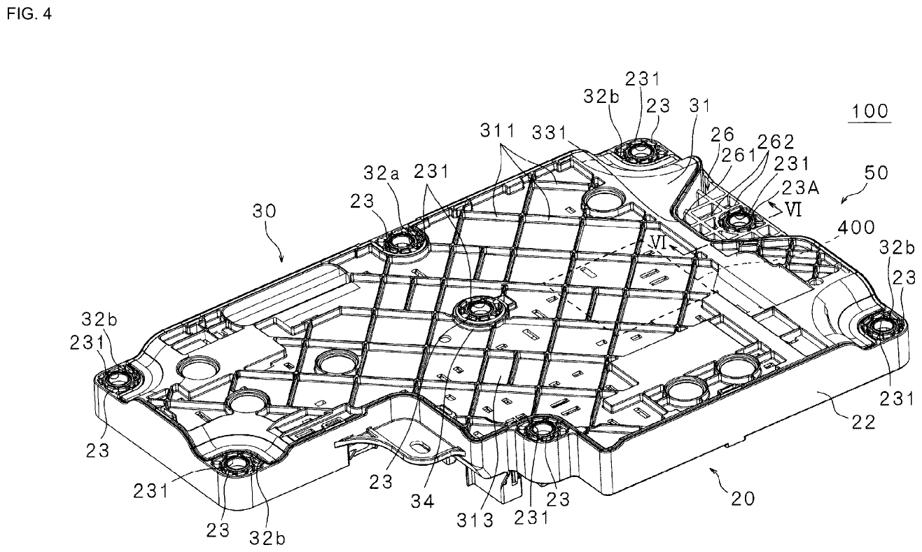

FIG. 1 is a perspective view of an electrical junction box 100 according to an embodiment, FIGS. 2A and 2B are respectively a plan view and a side view of the electrical junction box 100 according to the embodiment, FIG. 3 is an exploded view of the electrical junction box 100 according to the embodiment, and FIG. 4 is a bottom perspective view of the electrical junction box 100 according to the embodiment. FIG. 2A is a plan view of the electrical junction box 100, and FIG. 2B is a side view of the electrical junction box 100.

The electrical junction box 100 is attached to the outside of an object such as a battery pack 200 (see FIG. 2) of an EV (Electric Vehicle). For convenience of description, FIG. 2B shows a state in which the electrical junction box 100 is attached to the battery pack 200.

The electrical junction box 100 includes a housing 50 that accommodates, for example, a fuse, a substrate, and so on. The housing 50 is a flat housing that is substantially rectangular in a plan view, with one corner of one end portion in the lengthwise direction thereof being cut out in a stepped shape. The housing 50 is made of resin, for example, and includes a lower case 30 (a second case) that is attached to the aforementioned object, and an upper case 20 (a first case) that covers the lower case 30. For convenience of description, the upper case 20 side will be referred to as the top and the lower case 30 side will be referred to as the bottom.

The lower case 30 is box-shaped, with one surface on the upper case 20 side being open to form an opening 36.

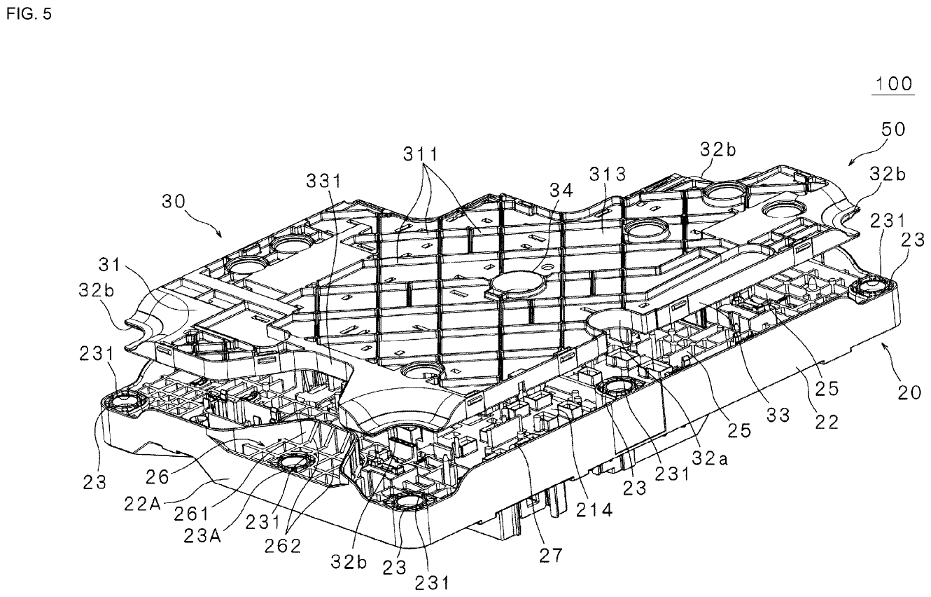

The upper case 20 is also box-shaped, with one surface on the lower case 30 side being open to form an opening 27 (see FIG. 5). The upper case 20 is slightly larger than the lower case 30 in both the dimension in the aforementioned lengthwise direction and the dimension in widthwise direction orthogonal to the aforementioned lengthwise direction, and covers the opening 36 of the lower case 30. In other words, the opening 27 of the upper case 20 is closed by the lower case 30.

The lower case 30 includes a bottom wall 31 whose outer side is in contact with the aforementioned object, and a side wall 33 extending perpendicularly from the edge of the bottom wall 31 toward the upper case 20. The lower case 30 has ribs respectively formed at a plurality of positions on the inner side thereof (see FIG. 3).

The bottom wall 31 of the lower case 30 has recesses 32b formed at both ends thereof in the aforementioned lengthwise direction, and a recess 32a formed in an intermediate portion thereof. The recess 32a and the recesses 32b are formed in the upper case 20 at positions corresponding to fastening portions 23, which will be described later.

More specifically, the recesses 32b are formed at both corners of both ends of the lower case 30. Each recess 32b is substantially rectangular in a plan view, and the side wall 33 of each recess 32b is bent at a substantially right angle and the recessed corners are chamfered (see FIG. 3).

The recess 32a is formed in an intermediate portion of the longer side of the lower case 30. The recess 32a is substantially rectangular in a plan view. At the recess 32a, the side wall 33 is recessed inwardly of the lower case 30, and the recessed corners are chamfered (see FIG. 3).

In the side wall 33 of the lower case 30, a portion corresponding to a strength reinforcing portion 26 of the upper case 20, which will be described in detail later, is recessed inwardly of the lower case 30. More specifically, a portion corresponding to an inner wall 261 of the strength-reinforcing portion 26 in the side wall 33 of the lower case 30 has a curved portion 331 curved following the shape of the inner wall 261 (see FIG. 4). After the assembly of the upper case 20 and the lower case 30 is complete, the curved portion 331 abuts against the inner wall 261 from the inside.

Furthermore, a through tube 34 is formed in a substantially central portion of the bottom wall 31, into which a fastening portion 23 of the upper case 20 is inserted. The through tube 34 has a cylindrical shape and passes through the bottom wall 31 in the thickness direction. That is to say, the axis of the through tube 34 extends in the thickness direction of the bottom wall 31, one side protrudes perpendicularly from the inner surface 312 of the bottom wall 31, and the other side protrudes perpendicularly from the outer surface 313 of the bottom wall 31. The fastening portion 23 is fitted into the through tube 34 and protrudes from the lower-side end of the through tube 34. In addition, the outer surface 313 of the bottom wall 31 has ribs 311 arranged in a grid shape so as to protrude therefrom, for example.

The upper case 20 has a top wall 21 (one wall) facing the bottom wall 31 of the lower case 30, and a side wall 22 that is provided along the periphery of the top wall 21 and protrudes in the top-bottom direction.

An outer surface 211 of the top wall 21 is provided with various connection portions 212 at a plurality of positions, which are used for connection to another device. A substantially central portion of the outer surface 211 of the top wall 21 is provided with a plurality of mounting seats 213 for relays 400. The relays 400 (electronic components) with a coil winding are mounted on the mounting seat 213. That is to say, the relays 400 are separated from the side wall 22 of the upper case 20. For the sake of convenience, the relays 400 are not shown in FIG. 3.

A plurality of outer ribs 24 are provided on the outer surface 211 of the top wall 21 so as to protrude therefrom. The outer ribs 24 include first outer ribs 24a for preventing warping caused by gravity and second outer ribs 24b for preventing warping caused by a difference in thermal expansion (see FIG. 3).

Each first outer rib 24a has a triangular plate shape and is provided mainly at the peripheral edge of the top wall 21. That is to say, the dimension in the top-bottom direction of each first outer rib 24a decreases in a direction from the central portion to the peripheral edge of the top wall 21. As described above, the first outer ribs 24a prevent the top wall 21 from warping due to the weight of the relays 400 (see FIGS. 1 and 2) mounted on the central portion thereof.

Each second outer rib 24b has a plate shape and is provided on end portions of the top wall 21 in the aforementioned lengthwise direction. For convenience, the present embodiment describes an example in which the second outer ribs 24b are provided only on one end portion of the top wall 21, but the present disclosure is not limited to such an example, and the second outer ribs 24b may be provided on both end portions.

Furthermore, the upper case 20 is provided with fastening portions 23 and 23A used to attach the housing 50 (the electrical junction box 100) to the aforementioned object, on both end portions and the intermediate portion in the aforementioned lengthwise direction thereof.

In the upper case 20, as described above, fastening portions 23 are provided at the two corners in the widthwise direction of one end portion in the longitudinal direction of which one corner is cut out in a stepped shape, and fastening portions 23 are also provided at the two corners in the widthwise direction of the other end portion opposite to the aforementioned one end portion. In the aforementioned other end portion of the upper case 20, a fastening portion 23A (attachment portion) is provided on an intermediate portion in the widthwise direction. That is to say, the fastening portion 23A is provided on an intermediate portion in the extension direction (widthwise direction) of a side wall 22A relating to the aforementioned other end portion, in the vicinity of the side wall 22A.

Furthermore, in the upper case 20, three fastening portions 23 are lined up in aforementioned widthwise direction on an intermediate portion in the aforementioned lengthwise direction. Of these three fastening portions 23, the fastening portion 23 provided for the intermediate portion in the aforementioned widthwise direction (hereinafter, the central fastening portion 23) is fitted into the through tube 34 of the lower case 30. The lower end of the central fastening portion 23 slightly protrudes from the lower-side end of the through tube 34, and the lower end surface of the central fastening portion 23 is exposed to the outside. In addition, as described above, the other fastening portions 23 are provided inside the recess 32a and 32b of the lower case 30.

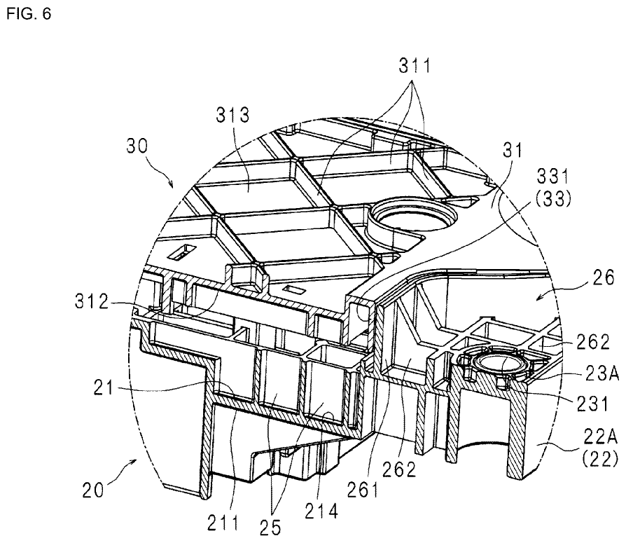

Each fastening portion 23 is provided on an inner surface 214 of the top wall 21 facing the bottom wall 31, so as to protrude therefrom (see FIGS. 5 and 6). The other fastening portions 23 and 23A except for the aforementioned central fastening portion 23 are provided in the vicinity of the side wall 22 (see FIG. 2A).

A plurality of inner ribs 25 are provided on the inner surface 214 of the top wall 21 so as to protrude therefrom (see FIGS. 5 and 6). Each of the plurality of inner ribs 25 has a plate shape.

Each of the fastening portions 23 and 23A (hereinafter also simply referred to as the fastening portions 23) is made of resin and has a cylindrical shape with a bottom and is open on the top wall 21 side. A fixing through hole 231 is formed in the bottom of each fastening portion 23, which is used when attaching the housing 50 to the aforementioned object (see FIG. 4). The housing 50 (the electrical junction box 100) can be attached to the aforementioned object by inserting screws (not shown) from the object into the fixing through holes 231 of the fastening portions 23 and screwing the screws into nuts (not shown) provided in the fastening portions 23.

The upper case 20 is provided with the strength-reinforcing portion 26. The strength-reinforcing portion 26 partially reinforces the strength of the upper case 20, and suppresses vibration of the relays 400 caused by vibration of the vehicle to which the electrical junction box 100 is attached. The strength-reinforcing portion 26 is provided for a central portion of the side wall 22A in the extension direction thereof.

FIG. 5 is an exploded view of the electrical junction box 100 according to the embodiment in an upside-down state, and FIG. 6 is a vertical cross-sectional view taken along the VI-VI line in FIG. 4.

For convenience of description, the following describes an example in which the strength-reinforcing portion 26 is provided only for the intermediate portion, in the extension direction (widthwise direction), of the side wall 22A of the other end portion of the upper case 20, but the present disclosure is not limited to such an example.

The strength-reinforcing portion 26 is provided in the vicinity of the side wall 22A. That is to say, the strength-reinforcing portion 26 is provided over a range from the central portion of the side wall 22A to the vicinity of the mounting position of the relay 400 (see the dashed line in FIG. 4).

The strength-reinforcing portion 26 is provided on the inner side with respect to the side wall 22A and has the plate-shaped inner wall 261 that is curved so as to protrude toward the relay 400. In other words, the inner wall 261 is provided for the inner surface of the side wall 22A, has a substantially U shape in a plan view, and has a curved plate shape so that the distance from the side wall 22A is larger at a position farther from each end portion. The dimension of the inner wall 261 is larger than that of the side wall 22A in the top-bottom direction. The inner wall 261 is provided so as to face the inner surface of the side wall 22A.

Ribs 262 are provided in the upper case 20 between the inner wall 261 and the side wall 22A, i.e., in the portion surrounded by the inner wall 261 and the side wall 22A. The ribs 262 are arranged in a grid shape, for example.

Furthermore, a portion of the strength-reinforcing portion 26 surrounded by the inner wall 261 and the side wall 22A is provided with the above-described fastening portion 23A. The fastening portion 23A is provided in the vicinity of the side wall 22A. The shape of the fastening portion 23A has already been described, and a detailed description thereof will be omitted.

A vehicle vibrates while traveling, and the electrical junction box 100 attached to the vehicle also vibrates at the same time in accordance with the vibration of the vehicle. Such vibration of the electrical junction box 100 may cause loosening of the screw connection between the electrical junction box 100 and the vehicle.

As described above, the relays 400 in the electrical junction box 100 are separated from the side wall 22 of the upper case 20 and are provided on a substantially central portion of the outer surface 211 of the top wall 21 for convenience of replacement and other operations and for ease of circuit configuration, for example. That is to say, the relays 400 are provided in the central portion of the plate member (the top wall 21), which is most susceptible to deformation in the top-bottom direction. In addition, since the relays 400 have a coil winding, they are heavier and more likely to vibrate than other electronic components.

That is to say, the relays 400 vibrate in accordance with the vibration of the electrical junction box 100 and provide further vibration to the electrical junction box 100. Therefore, the vibration of the relays 400 increases the amount of vibration of the electrical junction box 100, which further loosens the screw connection between the electrical junction box 100 and the vehicle, and therefore needs to be suppressed.

As described above, the electrical junction box 100 according to the present embodiment is provided with the strength-reinforcing portion 26 on the side wall 22A. The strength-reinforcing portion 26 is provided in intermediate portion of the side wall 22A in the extension direction, which is flexible in the thickness direction, and ribs 262 are formed in the range from the side wall 22A to the vicinity of the relays 400. The vibration direction of the relays 400, i.e., the top-bottom direction, is a direction orthogonal to the thickness direction of the side wall 22A, and the side wall 22A is unlikely to deform in the top-bottom direction.

As described above, the strength of the top wall 21 is increased by the strength reinforcing portion 26, and vibration of the relays 400 is suppressed.

In addition, in the electrical junction box 100 according to the present embodiment, as described above, the strength-reinforcing portion 26 has an inner wall 261, and the inner wall 261 faces the inner surface of the side wall 22A and protrudes towards the relays 400. Therefore, like the side wall 22A, the inner wall 261 is also unlikely to deform in the top-bottom direction, and since the inner wall 261 protrudes (curves) toward the relays 400 and its dimension in the top-bottom direction is larger than that of the side wall 22A, the inner wall 261 is less likely to deform in the top-bottom direction than the side wall 22A. Therefore, the strength-reinforcing portion 26 can more effectively suppress the vibration of the relays 400.

Furthermore, in the electrical junction box 100 according to the present embodiment, as described above, the lower case 30 has a curved portion 331 at the position corresponding to the inner wall 261 of the strength-reinforcing portion 26. The curved portion 331 is recessed toward the relays 400 following the shape of the inner wall 261, and abuts against the inner wall 261 from the inside. Like the inner wall 261, the thickness direction of the curved portion 331 is orthogonal to the top-bottom direction, and the curved portion 331 is curved toward the relays 400, so that the curved portion 331 is unlikely to deform in the vertical direction.

Therefore, in the electrical junction box 100 according to the present embodiment, the vibration of the relays 400 is suppressed more effectively.

In addition, as described above, in the electrical junction box 100 according to the present embodiment, a fastening portion 23A is provided in the strength-reinforcing portion 26. The fastening portion 23A is a portion that is fixed to the aforementioned object by screwing, and therefore is unlikely to deform in the top-bottom direction. Therefore, the strength-reinforcing portion 26 can reliably suppress the vibration of the relays 400.

The above description describes an example in which the strength-reinforcing portion 26 is provided at only one position for the central portion of the side wall 22A, but the present disclosure is not limited to such an example. For example, the strength-reinforcing portion 26 may be provided for each of the central portions of two portions of the side wall 22 that face each other in the aforementioned lengthwise direction, or for each of the central portions of two portions of the side wall 22 that face each other in the aforementioned widthwise direction. Alternatively, the strength-reinforcing portion 26 may be provided for each of the central portions of two portions of the side wall 22 that face each other in the aforementioned lengthwise direction and for each of the central portions of two portions of the side wall 22 that face each other in the aforementioned widthwise direction.

The embodiments disclosed herein should be considered to be illustrative and not restrictive in all respects. The scope of the present disclosure is defined by the claims, not by the meaning described above, and is intended to include all modifications within the meaning and scope of the claims.

The matters described in each embodiment can be combined with each other. In addition, the independent claims and dependent claims in the appended claims may be combined in any combination, regardless of reference form. Furthermore, although the appended claims are written in a format in which one claim refers to two or more other claims (multiple dependent claim format), the claims are not limited to such a format. Claims may be written in a format in which one multiple dependent claim refers to one or more other multiple dependent claims (multi-multi dependent claim).

1. An electrical junction box comprising: a housing; and an electronic component disposed on one wall that is adjacent to a side wall of the housing so as to be separated from the side wall,
wherein a strength-reinforcing portion is provided so as to extend from a central portion of the side wall to a vicinity of the electronic component.

2. The electrical junction box according to claim 1,
wherein the housing includes a first case that includes the side wall and the one wall, and the strength-reinforcing portion
is provided in the first case, and
includes an inner wall provided on an inner side with respect to the side wall and curved so as to protrude toward the electronic component, and a rib provided between the inner wall and the side wall.

3. The electrical junction box according to claim 2,
wherein the housing includes a second case that closes an opening of the first case formed so as to face the one wall, and
a side wall of the second case includes a curved portion corresponding to the inner wall.

4. The electrical junction box according to claim 1, wherein the strength-reinforcing portion includes an attachment portion that is used to attach the electrical junction box to an object.

5. The electrical junction box according to claim 2, wherein the strength-reinforcing portion includes an attachment portion that is used to attach the electrical junction box to an object.

6. The electrical junction box according to claim 3, wherein the strength-reinforcing portion includes an attachment portion that is used to attach the electrical junction box to an object.
